(19) United States
(12) Patent Application Publication
(10) Pub. No.: US 2012/0216859 A1
(43) Pub. Date: Aug. 30, 2012

(54) BACK SHEET FOR SOLAR CELL, AND SOLAR CELL MODULE

(75) Inventors: Satoshi Okamoto, Tsukuba-shi (JP); Tomoya Hosoda, Tsukuba-shi (JP)

(73) Assignee: Sumitomo Chemical Company, Limited

(21) Appl. No.: 13/390,932

(22) PCT Filed: Aug. 10, 2010
(86) PCT No.: PCT/JP2010/063559

§ 371 Date: May 7, 2012

(30) Foreign Application Priority Data
Aug. 17, 2009 (JP) 2009-188401

(51) Int. Cl. H01L 31/0216; B32B 27/36; C08G 63/60

(52) U.S. Cl. 136/256; 528/190; 428/480

(57) ABSTRACT

An object of the present invention is to provide a back sheet for a solar cell that improves weather resistance while also being advantageous in terms of cost. In a back sheet 7 for a solar cell of a preferred embodiment, a liquid crystal polyester that composes a liquid crystal polyester base material is formed of structural units represented by the following formulas (1), (2) and (3). When a total of divalent aromatic groups Ar¹, Ar² and Ar³ contained in the formulas (1), (2) and (3) is defined to be 100 mol %, a 2,6-naphthalenediyl group is contained at 40 mol % or more therein:

—O—Ar¹—CO— (1)

—CO—Ar²—CO— (2)

—O—Ar³—O— (3)

(wherein, Ar¹ represents one or more types of groups selected from the group consisting of a 2,6-naphthalenediyl group, 1,4-phenylene group and 4,4′-biphenylene group, and Ar² and Ar³ respectively and independently represent one or more types of groups selected from the group consisting of a 2,6-naphthalenediyl group, 1,4-phenylene group, 1,3-phenylene group and 4,4′-biphenylene group).

### TECHNICAL FIELD

The present invention relates to a back sheet for a solar cell, and to a solar cell module composed by using this back sheet for a solar cell.

### BACKGROUND ART

Solar cells have recently attracted attention as clean energy sources free of environmental contamination in response to a growing awareness of environmental issues. Extensive research has been conducted on solar cells from the perspective of utilizing solar energy as a useful energy resource, and solar cells have come to be used practically as a result thereof. Typical known examples of solar cells include crystalline silicon solar cells, polycrystalline silicon solar cells, amorphous silicon solar cells, copper iridium selenide solar cells and compound semiconductor solar cells.

These solar cells are provided with a front protective sheet on the side thereof where sunlight enters for the purpose of protecting the front surface, and are provided with a back sheet (back protective sheet) on the opposite side from the side where sunlight enters for the purpose of protecting the solar cell element.

A back sheet in which a heat-resistant polyolefin-based resin film is provided on a film having a vapor-deposited layer on one side of a base film (see, for example, Patent Literature 1), a back sheet obtained by laminating a colored polyester-based resin layer on a base having an inorganic vapor-deposited layer (see, for example, Patent Literature 2), and a back sheet obtained by laminating liquid crystal polyester on a base having a metal foil (see, for example, Patent Literature 3) are known conventional examples of this type of back sheet for use in a solar cell.

On the other hand, a known example of a film having weather resistance is a back sheet that uses a fluorine-based resin film for the outermost layer (see, for example, Patent Literatures 4 and 5).

### CITATION LIST

### Patent Literature

Patent Literature 1: Japanese Patent Application Laid-open No. 2004-200322
Patent Literature 2: Japanese Patent Application Laid-open No. 2004-223925
Patent Literature 3: Japanese Patent Application Laid-open No. 2002-64213
Patent Literature 4: Japanese Patent Application Laid-open No. 2003-347570
Patent Literature 5: Japanese Patent Application Laid-open No. 2004-352966

### SUMMARY OF INVENTION

### Technical Problem

However, in the technologies proposed in Patent Literature 1 to 3, the polyolefin-based resin and polyester-based resin used in the resin sheets of these back sheets do not demonstrate superior weather resistance (outdoor weather resistance). Thus, when solar cell modules provided with these back sheets are used for an extended period of time, there was the risk of the output of the solar cell modules decreasing or the appearance of the back sheet for the solar cell being impaired. Consequently, since the resulting solar cell modules did not always demonstrate adequate weather resistance, there has been a desire to further improve the weather resistance thereof.

In addition, in the technologies proposed in Patent Literatures 4 and 5, although it is necessary to use a fluorine-based resin film, this fluorine-based resin film had the disadvantage of being expensive.

Therefore, with the foregoing in view, an object of the present invention is to provide a back sheet for a solar cell and a solar cell module having superior weather resistance that are also advantageous in terms of cost.

### Solution to Problem

As a result of conducting extensive studies to achieve this object, the inventors of the present invention found that a liquid crystal polyester having a specific structure demonstrates a high strength retention rate and low water vapor permeability, thereby leading to completion of the present invention.

Namely, a first back sheet for a solar cell is a back sheet for a solar cell that contains a liquid crystal polyester base material, wherein the liquid crystal polyester that composes the liquid crystal polyester base material is formed of structural units represented by the following formulas (1), (2) and (3), and when a total of divalent aromatic groups Ar¹, Ar² and Ar³ contained in the formulas (1), (2) and (3) is defined to be 100 mol %, a 2,6-naphthalenediyl group is contained at 40 mol % or more in these aromatic groups:

—O—Ar¹—CO— (1)

—CO—Ar²—CO— (2)

—O—Ar³—O— (3)

(wherein, Ar¹ represents one or more types of groups selected from the group consisting of a 2,6-naphthalenediyl group, 1,4-phenylene group and 4,4′-biphenylene group, Ar² and Ar³ respectively and independently represent one or more types of groups selected from the group consisting of a 2,6-naphthalenediyl group, 1,4-phenylene group, 1,3-phenylene group and 4,4′-biphenylene group, and Ar¹, Ar² and Ar³ may have as a substituent thereof a halogen atom, alkyl group having 1 to 10 carbon atoms, or aryl group having 6 to 20 carbon atoms).

In addition, a second back sheet for a solar cell is characterized in that, in addition to the composition of the first back sheet for a solar cell, the flow starting temperature of the liquid crystal polyester is 280° C. or higher.

In addition, a third back sheet for a solar cell is characterized in that, in addition to the composition of the first or second back sheet for a solar cell, a maximum value of melt tension of the liquid crystal polyester as measured at a higher temperature than the flow starting temperature is 0.0098 N or more.

In addition, a fourth back sheet for a solar cell is characterized in that, in addition to the composition of any of the first to third back sheets for a solar cell, a water vapor barrier layer is laminated onto the liquid crystal polyester base material.

Moreover, a solar cell module according to a preferable embodiment is characterized in that any of the first to fourth back sheets for a solar cell are provided on the back of a solar cell element.

### Advantageous Effects of Invention

According to the present invention, as a result of applying a liquid crystal polyester having a specific structure as a liquid crystal polyester that composes a liquid crystal polyester base material of a back sheet for a solar cell, since water vapor permeability decreases simultaneous to increasing strength retention rate, a back sheet for a solar cell and a solar cell module can be provided that have superior weather resistance while also being advantageous in terms of cost.

### BRIEF DESCRIPTION OF DRAWING

FIG. 1 is a cross-sectional view showing a solar cell module according to a first embodiment.

### DESCRIPTION OF EMBODIMENTS

The following provides an explanation of preferred embodiments.

### First Embodiment

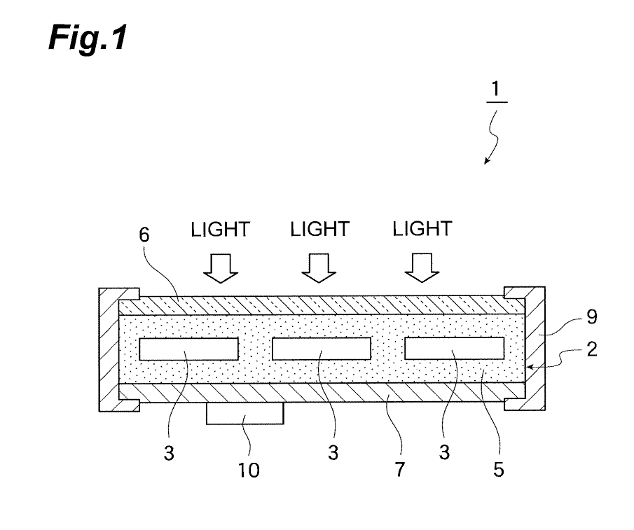

FIG. 1 shows a schematic cross-sectional view of a solar cell module of a first embodiment.

A solar cell module 1 according to the first embodiment has, as shown in FIG. 1, a solar cell element 2 that converts light energy to electrical energy using photoelectromotive force. This solar cell element 2 has a structure in which three photoelectric conversion cells 3 composed of a semiconductor such as silicon are sequentially connected in series, and these three photoelectric conversion cells 3 are molded in a translucent sealing material 5.

A translucent surface protective glass 6 is installed on the front surface (surface on the side that receives sunlight) of the solar cell element 2. A back sheet 7 (back sheet for a solar cell) having superior weather resistance and water vapor impermeability (gas impermeability) is affixed to the back surface of the solar cell device 2 (surface on the opposite side from the side that receives sunlight) for the purpose of protecting and moisture-proofing the solar cell device 2. In addition, an aluminum frame 9 is attached to the sides of the solar cell element 2 so as to integrally hold the solar cell element 2, the front surface protective glass 6 and the back sheet 7 by enabling these components to be inserted therein. Moreover, a terminal box 10 is attached to the back of the back sheet 7.

Here, an adhesive mainly composed of a transparent resin such as ethylene-vinyl acetate copolymer (EVA), polyvinyl butyral, silicone resin, epoxy resin, fluorinated polyimide resin, acrylic resin or polyester resin can be used for the sealing material 5. These resins may also contain an ultraviolet absorber for the purpose of improving weather resistance.

In addition, the back sheet 7 is mainly composed of a liquid crystal polyester base material. The liquid crystal polyester that composes this liquid crystal polyester base material is composed of structural units represented by the following formulas (1), (2) and (3), and when the total of divalent aromatic groups Ar¹, Ar² and Ar³ contained in the formulas (1), (2) and (3) is defined to be 100 mol %, a 2,6-naphthalenediyl group is contained at 40 mol % or more in these aromatic groups. In addition, the flow starting temperature of the liquid crystal polyester is preferably 280° C. or higher, the maximum value of the melt tension of the liquid crystal polyester as measured at a higher temperature than the flow starting temperature is preferably 0.0098 N or more, and the liquid crystal polyester demonstrates optical anisotropy when melted:

—O—Ar¹—CO— (1)

—CO—Ar²—CO— (2)

—O—Ar³—O— (3)

(wherein, Ar¹ represents one or more types of groups selected from the group consisting of a 2,6-naphthalenediyl group, 1,4-phenylene group and 4,4′-biphenylene group, Ar² and Ar³ respectively and independently represent one or more types of groups selected from the group consisting of a 2,6-naphthalenediyl group, 1,4-phenylene group, 1,3-phenylene group and 4,4′-biphenylene group, and Ar¹, Ar² and Ar³ may have as a substituent thereof a halogen atom, alkyl group having 1 to 10 carbon atoms, or aryl group having 6 to 20 carbon atoms).

Here, the liquid crystal polyester refers to polyester that demonstrates optical anisotropy when melted at a temperature of 450° C. or lower. This type of liquid crystal polyester can be obtained by selecting and polymerizing raw material monomers consisting of monomers containing a 2,6-naphthalenediyl group and monomers having other aromatic rings in the production stage thereof so that structural units having a 2,6-naphthalenediyl group are contained at 40 mol % or more in the resulting liquid crystal polyester.

In this manner, in a liquid crystal polyester composed of structural units represented by the formulas (1), (2) and (3), when the total of divalent aromatic groups Ar¹, Ar² and Ar³ is defined to be 100 mol %, weather resistance of the back sheet 7 can be enhanced since 2,6-naphthalenediyl groups in these aromatic groups are contained at 40 mol % or more.

In addition, the production cost of the back sheet 7 can be reduced since it is not necessary to use expensive materials such as a fluorine-based resin film.

In the liquid crystal polyester used in the present embodiment, when the total of divalent aromatic groups Ar¹, Ar² and Ar³ is defined to be 100 mol %, preferably 2,6-naphthalenediyl groups are contained at 50 mol % or more, more preferably 2,6-naphthalenediyl groups are contained at 65 mol % or more, and still more preferably 2,6-naphthalenediyl groups are contained at 70 mol % or more in these aromatic groups. In this manner, a liquid crystal polyester containing a larger number of 2,6-naphthalenediyl groups is able to further improve weather resistance of the back sheet 1 for a solar cell.

In addition, when the total of structural units (1), (2) and (3) that compose the liquid crystal polyester (to also be referred to as the total of all structural units) is defined to be 100 mol %, the total of structural units derived from an aromatic hydroxycarboxylic acid represented by (1) is preferably 30 mol % to 80 mol %, the total of structural units derived from an aromatic dicarboxylic acid represented by (2) is preferably 10 mol % to 35 mol %, and the total of structural units derived from an aromatic diol represented by (3) is preferably 10 mol % to 35 mol %.

In addition, the liquid crystal polyester used in the present embodiment is preferably a completely aromatic liquid crystal polyester. Here, a completely aromatic liquid crystal polyester refers to a resin in which the divalent aromatic groups represented by Ar¹, Ar² and Ar³ are linked with ester bonds (—C(O)O—). In a completely aromatic liquid crystal polyester, the content ratio of structural units represented by formula (2) to the total of all structural units and the content ratio of structural units represented by formula (3) to the total of all structural units are substantially equal. Since a completely aromatic liquid crystal polyester has superior weather resistance, it can be preferably used as a material of the back sheet 7.

Here, if the content ratios of structural units derived from an aromatic hydroxycarboxylic acid, structural units derived from an aromatic dicarboxylic acid and structural units derived from an aromatic diol to the total of all structural units are within the previously described ranges, in addition to the liquid crystal polyester demonstrating advanced liquid crystal properties, the liquid crystal polyester also has superior melt processability, thereby making this preferable.

Furthermore, the content ratio of structural units derived from an aromatic hydroxycarboxylic acid to the total of all structural units is more preferably 40 mol % to 70 mol % and particularly preferably 45 mol % to 65 mol %. On the other hand, the content ratios of structural units derived from an aromatic dicarboxylic acid and structural units derived from an aromatic diol to the total of all structural units are each more preferably 15 mol % to 30 mol % and particularly preferably 17.5 mol % to 27.5 mol %.

Examples of monomers that form a structural unit represented by formula (1) include 2-hydroxy-6-naphthoic acid, p-hydroxybenzoic acid and 4-(4-hydroxyphenyl)benzoic acid. Moreover, examples of these monomers also include monomers in which a hydrogen atom of a benzene ring or naphthalene ring thereof is substituted with a halogen atom, alkyl group having 1 to 10 carbon atoms or aryl group. Here, an example of a monomer that forms a structural unit having a 2,6-naphthalenediyl group in the present embodiment is 2-hydroxy-6-naphthoic acid. A hydrogen atom of the naphthalene ring of this 2-hydroxy-6-naphthoic acid may be substituted with a halogen atom, alkyl group having 1 to 10 carbon atoms or aryl group. Moreover, it may also be used after converting to an ester-forming derivative to be subsequently described.

Examples of monomers that form a structural unit represented by formula (2) include 2,6-naphthalene dicarboxylic acid, terephthalic acid, isophthalic acid and biphenyl-4,4′-dicarboxylic acid. Examples of these monomers also include monomers in which a hydrogen atom of a benzene ring or naphthalene ring thereof is substituted with a halogen atom, alkyl group having 1 to 10 carbon atoms or aryl group. Here, an example of a monomer that forms a structural unit having a 2,6-naphthalenediyl group in the present embodiment is 2,6-naphthalene dicarboxylic acid. A hydrogen atom of the naphthalene ring of this 2,6-naphthalene dicarboxylic acid may be substituted with a halogen atom, alkyl group having 1 to 10 carbon atoms or aryl group. Moreover, it may also be used after converting to an ester-forming derivative to be subsequently described.

Examples of monomers that form a structural unit represented by formula (3) include 2,6-naphthol, hydroquinone, resorcin and 4,4′-dihydroxybiphenyl. Examples of these monomers also include monomers in which a hydrogen atom of a benzene ring or naphthalene ring thereof is substituted with a halogen atom, alkyl group having 1 to 10 carbon atoms or aryl group. Here, an example of a monomer that forms a structural unit having a 2,6-naphthalenediyl group in the present embodiment is 2,6-naphthol. A hydrogen atom of the naphthalene ring of this 2,6-naphthol may be substituted with a halogen atom, alkyl group having 1 to 10 carbon atoms or aryl group. Moreover, it may also be used after converting to an ester-forming derivative to be subsequently described.

As was previously described, any of the structural units represented by formulas (1), (2) and (3) may also have the above-mentioned substituents (halogen atom, alkyl group having 1 to 10 carbon atoms and aryl group) in an aromatic ring (benzene ring or naphthalene ring). Examples of halogen groups among these substituents include a fluorine atom, chlorine atom, bromine atom and iodine atom. In addition, examples of alkyl groups having 1 to 10 carbon atoms include alkyl groups represented by a methyl group, ethyl group, propyl group, butyl group, hexyl group, octyl group or decyl group. These alkyl groups may be linear or branched, and may also be alicyclic groups. Moreover, examples of aryl groups include aryl groups having 6 to 20 carbon atoms represented by a phenyl group or naphthyl group.

Monomers that form structural units represented by formula (1), (2) or (3) are preferably used in the form of an ester-forming derivative in order to facilitate polymerization during the course of producing the polyester. This ester-forming derivative refers to a monomer that has a group promoting an ester-forming reaction. Specific examples thereof include highly reactive derivatives such as ester-forming derivatives in which a carboxyl group in a molecule thereof has been converted to an acid halide or acid anhydride, or ester-forming derivatives in which a hydroxyl group in a molecule thereof has been converted to a lower carboxylic acid ester group.

The liquid crystal polyester described in Japanese Patent Application Laid-open No. 2005-272810 is preferable as a preferable monomer combination of the liquid crystal polyester used in the present embodiment from the viewpoints of improving heat resistance and melt tension. More specifically, the content ratio of a repeating structural unit of 2-hydroxy-6-naphthoic acid (I) is preferably 40 mol % to 74.8 mol %, the content ratio of a repeating structural unit of hydroquinone (II) is preferably 12.5 mol % to 30 mol %, the content ratio of a repeating structural unit of 2,6-naphthalene dicarboxylic acid (III) is preferably 12.5 mol % to 30 mol % and the content ratio of a repeating structural unit of terephthalic acid (IV) is preferably 0.2 mol % to 15 mol %, and the molar ratio of the repeating structural units represented by (III) and (IV) preferably satisfies the relationship of (III)/[(III)+(IV)]≧0.5.

More preferably, the content ratio to the total number of repeating structural units of (I) to (IV) above of the repeating structural unit of (I) is 40 mol % to 64.5 mol %, that of the repeating structural unit of (II) is 17.5 mol % to 30 mol %, that of the repeating structural unit of (III) is 17.5 mol % to 30 mol % and that of the repeating structural unit of (IV) is 0.5 mol % to 12 mol %, and the molar ratio of the repeating structural units represented by (III) and (IV) satisfies the relationship of (III)/[(III)+(IV)]≧0.6.

Even more preferably, the content ratio to the total number of repeating structural units of (I) to (IV) above of the repeating structural unit of (I) is 50 mol % to 58 mol %, that of the repeating structural unit of (II) is 20 mol % to 25 mol %, that of the repeating structural unit of (III) is 20 mol % to 25 mol % and that of the repeating structural unit of (IV) is 2 mol % to 10 mol %, and the molar ratio of the repeating structural units represented by (III) and (IV) satisfies the relationship of (III)/[(III)+(IV)]≧0.6.

In addition, although a known method can be employed to produce the liquid crystal polyester, the liquid crystal polyester is preferably produced using for the above-mentioned ester-forming derivative a derivative obtained by converting a hydroxyl group within a molecule of the monomer to an ester group using a lower carboxylic acid, and is particularly preferably produced using a derivative obtained by converting the hydroxyl group to an acyl group. Acylation can normally be achieved by reacting a monomer having a hydroxyl group with acetic anhydride. An ester-forming derivative obtained by this acylation facilitates the production of polyester by being able to be polymerized by elimination of acetic acid by condensation polymerization.

A known method (such as the method described in Japanese Patent Application Laid-open No. 2002-146003, for example) can be applied for the production method of the liquid crystal polyester. Namely, monomers corresponding to a structural unit having a 2,6-naphthalenediyl group are first selected for the monomers corresponding to the structural units represented by the above-mentioned formulas (1), (2) and (3) so as account for 40 mol % or more of all monomers. After converting to an ester-forming derivative as necessary, these monomers are subjected to melt condensation polymerization to obtain aromatic liquid crystal polyester having a comparatively low molecular weight (to be referred to as a “prepolymer”). Next, the prepolymer is crushed and subjected to solid phase polymerization by heating. The use of this solid phase polymerization makes it possible to increase molecular weight while facilitating the progression of polymerization.

The prepolymer obtained by melt condensation polymerization is formed into a powder by, for example, crushing after solidifying the prepolymer by cooling. The particle diameter of the powder is preferably an average of about 0.05 mm to 3 mm. A particle diameter of about 0.05 mm to 1.5 mm is particularly preferable since this accelerates the increase in the degree of polymerization of the aromatic liquid crystal polyester. In addition, a particle diameter of about 0.1 mm to 1.0 mm is even more preferable since the increase in degree of polymerization of the liquid crystal polyester is accelerated without causing sintering between powder particles.

Heating during solid phase polymerization is carried out while raising the temperature in an ordinary manner, and for example, is carried out by heating from room temperature to a temperature 20° C. or more lower than the flow starting temperature of the prepolymer. Although there are no particular limitations on the heating time at this time, it is preferably within 1 hour from the viewpoint of shortening the reaction time.

During production of the liquid crystal polyester, heating during solid phase polymerization is preferably carried out from a temperature 20° C. or more lower than the flow starting temperature of the prepolymer to a temperature of 280° C. or higher. Heating is preferably carried out at a heating rate of 0.3° C./min or less. This heating rate is preferably 0.1° C./min to 0.15° C./min. If the heating rate is 0.3° C./min or less, there is less likelihood of the occurrence of sintering between powder particles, thereby making this preferable from the viewpoint of facilitating production of liquid crystal polyester having a high degree of polymerization.

Here, although varying according to the type of monomer of the aromatic diol or aromatic dicarboxylic acid component of the resulting liquid crystal resin, the reaction during solid phase polymerization is preferably carried out for 30 minutes or more at a temperature of 280° C. or higher, and preferably within a range of 280° C. to 400° C., in order to increase the degree of polymerization of the liquid crystal polyester. From the viewpoint of thermal stability of the liquid crystal resin in particular, the reaction is preferably carried out for 30 minutes to 30 hours at a reaction temperature of 280° C. to 350° C., and more preferably carried out for 30 minutes to 20 hours at a reaction temperature of 285° C. to 340° C.

The flow starting temperature of the liquid crystal polyester according to the present embodiment refers to a value obtained by measuring pellets of the liquid crystal polyester (powder or pellets), obtained according to the above-mentioned production method, that are obtained by melt kneading using an extruder. A flow starting temperature of the pellets of 280° C. or higher is preferable from the viewpoint of improving heat resistance, and particularly heat resistance capable of withstanding solder reflow processing used as a high density mounting method. If the flow starting temperature is 290° C. to 380° C. in particular, heat resistance is high and decomposition and deterioration of the polymer during molding are inhibited, thereby making this preferable, while a flow starting temperature of 295° C. to 350° C. is more preferable.

Here, flow starting temperature is the temperature at which melt viscosity indicates 4800 Pa·s (48000 poise) when the liquid crystal polyester is extruded from a nozzle at a heating rate of 4° C./min and under a load of 9.8 MPa (100 kgf/cm²) using a capillary rheometer equipped with a die having an inner diameter of 1 mm and length of 10 mm (refer to, for example, Ekisho Polima—Gosei, Seikei, Oyo [Liquid Crystal Polymer: Synthesis, Molding and Applications], Naoyuki Koide, ed., pp. 95-105, CMC Publishing Co., Ltd., Jun. 5, 1987).

Next, an explanation is provided of a specific method for melt kneading the liquid crystal polyester (powder or pellets) obtained according to the above-mentioned production method using an extruder.

Pellets are obtained by melt kneading only a resin (powder or pellets) obtained according to the liquid crystal polyester production method using, for example, a single-screw or multi-screw extruder, and preferably a twin screw extruder, Banbury mixer or roller kneader over a temperature range from −10° C. to 100° C. higher than the flow starting temperature thereof. From the viewpoint of preventing thermal deterioration of the liquid crystal polyester, the temperature range is preferably within a range from −10° C. to 70° C. higher than the flow starting temperature, and more preferably a range from −10° C. to 50° C. higher than the flow starting temperature.

In addition, the liquid crystal polyester used in the present embodiment can be a liquid crystal polyester resin composition by containing a filler and the like therein.

Here, examples of fillers include inorganic fillers such as milled glass fibers, chopped glass fibers or other glass fibers, glass beads, hollow glass beads, glass powder, mica, talc, clay, silica, alumina, potassium titanate, wollastonite, calcium carbonate (including heavy, light and colloidal calcium carbonate), magnesium carbonate, basic magnesium carbonate, sodium sulfate, calcium sulfate, barium sulfate, calcium sulfite, aluminum hydroxide, magnesium hydroxide, calcium hydroxide, calcium silicate, silica sand, silica rock, quartz, titanium oxide, zinc oxide, iron oxide graphite, molybdenum, asbestos, silica alumina fibers, alumina fibers, gypsum fibers, carbon fibers, carbon black, white carbon, diatomaceous earth, bentonite, sericite, white sand loam or graphite, metallic or non-metallic whiskers such as potassium titanate whiskers, alumina whiskers, aluminum borate whiskers, silicon carbonate whiskers or silicon nitride whiskers, and mixtures of two or more types thereof. In particular, glass fibers, glass powder, mica, talc and carbon fibers are preferable.

In addition, the surface of the filler may be treated with a surface treatment agent. Examples of this surface treatment agent include reactive coupling agents such as a silane coupling agent, titanate coupling agent or borane coupling agent, and lubricants such as a higher fatty acid, higher fatty acid ester, higher fatty acid metal salt or fluorocarbon-based surfactant.

The amount of these fillers used is normally within the range of 0.1 parts by weight to 400 parts by weight, preferably within the range of 10 parts by weight to 400 parts by weight, and more preferably within the range of 10 parts by weight to 250 parts by weight based on 100 parts by weight of the aromatic liquid crystal polyester.

In addition, the liquid crystal polyester resin composition may also contain a thermoplastic resin other than liquid crystal polyester or an additive in addition to the above-mentioned filler.

Here, examples of the thermoplastic resin include polycarbonate resin, polyamide resin, polysulfone resin, polyphenylene sulfide resin, polyphenylene ether resin, polyether ketone resin and polyetherimide resin.

In addition, examples of additives include a mold release improvers such as fluororesin or metal soap, nucleating agents, antioxidants, stabilizers, plasticizers, lubricants, anti-coloring agents, colorants, ultraviolet absorbers, antistatic agents, lubricants and flame retardants.

The liquid crystal polyester resin composition can be produced by, for example, mixing the liquid crystal polyester obtained in the manner described above, a filler as described above, and as necessary, a thermoplastic resin and additive. Mixing at this time may be carried out using a mortar, Henschel mixer, ball mill or ribbon blender, or may be carried out using melt kneading machine such as a single-screw extruder, twin-screw extruder, Banbury mixer, roller, Brabender mixer or kneader. This mixing is preferably carried out under the above-mentioned melt kneading conditions.

The liquid crystal polyester used in the present embodiment is able to demonstrate a maximum value of melt tension as measured at a temperature higher than the flow starting temperature of pellets obtained by melt kneading the liquid crystal polyester (powder or pellets) obtained according to the above-mentioned production method of 0.0098 N or more (preferably 0.015 N or more and more preferably 0.020 N or more). Moreover, a liquid crystal polyester having a maximum value of melt tension measured at a temperature 25° C. higher than the flow starting temperature of 0.0098 N or more allows the stable production of a liquid crystal polyester base material.

This melt tension refers to tension (units: N) generated when pellets obtained by melt kneading the liquid crystal polyester (powder or pellets) obtained according to the above-mentioned production method are filled into a melt viscosity measurement tester (flow characteristics tester) followed by drawing a sample into the form of a thread and then breaking the sample while heating automatically with a variable speed winder under conditions of a cylinder barrel diameter of 1 mm and piston pushing speed of 5.0 mm/min.

A film or sheet obtained by subjecting the liquid crystal polyester to a T-die method in which molten resin wound after extruding from a T-die or an inflation film deposition method consisting of extruding a molten resin into a cylindrical shape from an extruder equipped with an annular die, cooling and then winding, a film or sheet obtained by hot pressing or melt casting, or a film or sheet obtained by uniaxially drawing or biaxially drawing a sheet obtained by injection molding or extrusion, can be used for the liquid crystal polyester base material used in the present embodiment. In the case of injection molding or extrusion molding, a film or sheet can be obtained by melt molding after dry blending a powder or pellets of the components during molding without having to go through a preliminary kneading step.

A uniaxially drawn film or biaxially drawn film obtained by winding while drawing a molten resin extruded from a T-die in the direction of the winder (machine direction) is used preferably in the T-die method.

Although able to be suitably set according to the composition of the resin composition, the set conditions of the extruder during deposition of the uniaxially drawn film are preferably such that the cylinder set temperature is within the range of 200° C. to 360° C. and more preferably within the range of 230° C. to 350° C. If the temperature is outside these ranges, the composition may undergo thermal decomposition or it may be difficult to deposit the film, thereby making this undesirable.

The slit interval of the T-die is preferably 0.2 mm to 2.0 mm and more preferably 0.2 mm to 1.2 mm. The draft ratio of the uniaxially drawn film is preferably within the range of 1.1 to 40, more preferably within the range of 10 to 40 and particularly preferably within the range of 15 to 35.

This draft ratio refers to the value obtained by dividing the cross-sectional surface area of the T-die slit by the cross-sectional area of the film (surface area of a cross-section perpendicular to the machine direction of the film). If the draft ratio is less than 1, film strength may become inadequate, while if the draft ratio exceeds 45, the surface smoothness of the film may become inadequate. This draft ratio can be set by controlling the set conditions of the extruder, winding speed and the like.

A biaxially drawn film can be obtained extruder set conditions similar to those used when depositing a uniaxially drawn film. Namely, a biaxially drawn film is obtained by a method in which melt extrusion of this composition is carried out under conditions such that the cylinder set temperature is preferably within the range of 200° C. to 360° C. and more preferably within the range of 230° C. to 350° C. and the slit interval is preferably within the range of 0.2 mm to 1.2 mm, and the molten sheet extruded from the T-die is simultaneously drawn in the machine direction and the direction perpendicular to the machine direction (transverse direction), or a sequential drawing method in which after having first drawn the molten sheet extruded from the T-die in the machine direction, the drawn sheet is drawn in the transverse direction by a tenter at a high temperature of 100° C. to 300° C. in the same step.

When obtaining a biaxially drawn film, the draw ratio thereof is preferably within the range of 1.2 times to 40 times in the machine direction and within the range of 1.2 times to 20 times in the transverse direction. If the draw ratio is outside these ranges, film strength of the composition may become inadequate or it may become difficult to obtain a film of uniform thickness.

An inflation film obtained by depositing a molten sheet extruded from a cylindrical die using an inflation method is preferably used for the liquid crystal polyester base material. Namely, the liquid crystal polyester base material obtained according to the above-mentioned method is supplied to a melt kneading extruder equipped with a die having an annular slit, melt kneading is carried out at a cylinder set temperature of 200° C. to 360° C. and preferably 230° C. to 350° C., and a molten resin is extruded upward or downward from the annular slit of the extruder in the form of a cylindrical film. The annular slit interval is normally 0.1 mm to 5 mm, preferably 0.2 mm to 2 mm and more preferably 0.6 mm to 1.5 mm. The diameter of the annular slit is normally 20 mm to 1000 mm and preferably 25 mm to 600 mm.

The melt extruded molten resin film was then expanded and drawn in the transverse direction (TD) perpendicular to the machine direction (MD) by applying a draft to the film in the machine direction (MD) while also blowing in air or an inert gas such as nitrogen gas from inside the cylindrical film.

During inflation molding (deposition), the blow ratio (draw ratio in transverse direction=diameter of inflation bubble/diameter of annular slit) is preferably 1.5 to 10 and more preferably 2.0 to 5.0, while the draw-down ratio (MD draw magnification=bubble take-up speed/resin discharge speed) is preferably 1.5 to 50 and more preferably 5.0 to 30. In addition, a so-called B shape (wine glass shape) is preferably selected for the shape of the bubble. If the set conditions during inflation deposition are outside the above-mentioned ranges, it may be difficult to obtain a high-strength liquid crystal polyester base material that has uniform thickness and is free of wrinkles, thereby making this undesirable.

The expanded film is normally taken up by passing through nip rollers after having air-cooled or water-cooled the circumference thereof.

During inflation deposition, conditions can be selected corresponding to the liquid crystal polyester base material so that the cylindrical molten film is expanded in a state having a uniform thickness and smooth surface.

Although there are no particular limitations thereon, the thickness of the liquid crystal polyester base material used in the present embodiment is preferably 3 μm to 1000 μm, more preferably 10 μm to 200 μm and even more preferably 12 μm to 150 μm. A liquid crystal polyester obtained according to this method has superior heat resistance and electrical insulating properties, can be made to be lightweight and thin-walled, has favorable mechanical strength, and is flexible and inexpensive.

In the present embodiment, the surface of the liquid crystal polyester base material can be preliminarily subjected to surface treatment. Examples of this surface treatment include corona discharge treatment, plasma treatment, flame treatment, sputtering treatment, solvent treatment, ultraviolet treatment, polishing treatment, infrared treatment and ozone treatment.

The liquid crystal polyester base material may be colorless or may contain a coloring component such as a pigment or dye. Examples of methods for incorporating a coloring component include a method in which a coloring component is kneaded in advance during film deposition, and a method in which a coloring component is printed onto the base material. In addition, a colored film and a colorless film may also be laminated prior to use.

### Second Embodiment

The solar cell module 1 according to the second embodiment has the same composition as that of the previously described first embodiment with the exception of having a water vapor barrier layer (not shown) laminated onto the liquid crystal polyester base material of the back sheet 7 for the purpose of further improving weather resistance of the back sheet 7.

A liquid crystal polyester base material vapor-deposited with a metal foil, metal oxide or non-metallic inorganic oxide can be used for this water vapor barrier layer.

Examples of metal foil that can be used include aluminum foil, iron foil and a zinc-coated steel sheet. The thickness thereof is preferably 10 μm to 100 μm. Furthermore, examples of methods used to laminate a metal foil onto the liquid crystal polyester base material include a method in which a metal foil is laminated onto a film composed of liquid crystal polyester by a known chemical vapor deposition method, sputtering method or vapor deposition method, and a method in which a metal sheet or metal thin film is adhered directly to a film composed of liquid crystal polyester.

On the other hand, a liquid crystal polyester base material in which a metal oxide or non-metallic inorganic oxide is vapor-deposited onto the liquid crystal polyester base material using a known vacuum deposition method, PVD method such as ion plating or sputtering, or CVD method such as plasma CVD or microwave CVD can be used as a liquid crystal polyester base material vapor-deposited with a metal oxide or non-metallic inorganic oxide.

Examples of metal oxides and non-metallic inorganic oxides used for this vapor deposition include oxides of silicon, aluminum, magnesium, calcium, potassium, tin, sodium, boron, titanium, lead, zirconium or yttrium. In addition, fluorides of alkaline metals or alkaline earth metals can also be used. These may be used alone or two or more types may be used in combination.

Although varying according to the material used, the thickness of the vapor deposited layer of these metal oxides or non-metallic inorganic oxides is preferably within the range of 5 nm to 250 nm and more preferably within the range of 40 nm to 100 nm.

In addition, although the vapor deposited layer of metal oxide or non-metallic inorganic oxide is at least provided on one side of the liquid crystal polyester base material, it may also be provided on both sides thereof. Moreover, in the case of using the metal oxide or non-metallic inorganic oxide used for vapor deposition as a mixture of two or more types, the vapor deposited film can be used as a mixture of different types of materials.

Moreover, although a film in which a metal oxide or non-metallic inorganic oxide is vapor-deposited on at least one side of the liquid crystal polyester base material can be used as a single layer of a water vapor barrier layer, it can also be used in the state of a laminate obtained by laminating two or more layers. In the case of laminating two or more layers, the layers can be laminated by using a known press or lamination method.

Thus, in the solar cell module 1 according to this second embodiment, in addition to increasing strength retention rate in the same manner as the first embodiment, since the back sheet 7 is composed of the liquid crystal polyester base material and a water vapor barrier layer, weather resistance can be further improved as a result of decreasing the water vapor permeability of the back sheet 7.

### Other Embodiments

Furthermore, although the above-mentioned first and second embodiments have provided an explanation of the solar cell module 1 provided with three photoelectric conversion cells 3, the number of the photoelectric conversion cells 3 is not particularly limited to three.

In addition, in the above-mentioned first and second embodiment, explanations were provided of the solar cell module 1 provided with the aluminum frame 9. However, the material of the frame 9 is not limited to aluminum, and the solar cell module 1 can also be composed while omitting the frame 9.

### EXAMPLES

The following provides an explanation of examples of the present invention. Furthermore, the present invention is not limited to the examples.

### Synthesis Example 1

1034.99 g (5.5 moles) of 2-hydroxy-6-naphthoic acid, 272.52 g (2.475 moles, 0.225 moles added in excess) of hydroquinone, 378.33 g (1.75 moles) of 2,6-naphthalene dicarboxylic acid, 83.07 g (0.5 moles) of terephthalic acid, 1226.87 g (12.0 moles) of acetic anhydride and 0.17 g of 1-methylimidazole as catalyst were added to a reactor equipped with a stirring apparatus, torque meter, nitrogen gas feed tube, thermometer and reflux condenser, and after stirring for 15 minutes at room temperature, the temperature was raised while stirring. When the internal temperature reached 145° C., stirring was continued for 1 hour while holding at the same temperature (145° C.).

Next, the temperature was raised from 145° C. to 310° C. over the course of 3 hours 30 minutes while distilling off distilled by-product acetic acid and unreacted acetic anhydride. The mixture was held at the same temperature (310° C.) for 3 hours to obtain liquid crystal polyester. The liquid crystal polyester obtained in this manner was then cooled to room temperature and crushed with a grinder to obtain powdered liquid crystal polyester (prepolymer) having a particle diameter of about 0.1 mm to 1 mm. This was designated as Synthesis Example 1.

The substantial copolymer molar fraction in the liquid crystal polyester of Synthesis Example 1 was 55.0 mol %:22.5 mol %:22.5 mol % when represented as the molar fraction of the structural unit represented by the above-mentioned formula (1) to the structural unit represented by the above-mentioned formula (2) to the structural unit represented by the above-mentioned formula (3). In addition, the copolymer molar fraction of 2,6-naphthalenediyl groups to the total number of aromatic groups contained in these structural units in the liquid crystal polyester of Synthesis Example 1 was 72.5 mol %.

### Synthesis Example 2

After raising the temperature of a powder obtained in the same manner as Synthesis Example 1 from 25° C. to 250° C. over the course of 1 hour, the temperature was raised from the same temperature (250° C.) to 293° C. over the course of 5 hours followed by holding at that temperature (293° C.) for 5 hours to carry out solid phase polymerization. Following solid phase polymerization, the resulting powder was subsequently cooled to obtain powdered liquid crystal polyester. This was designated as Synthesis Example 2.

The substantial copolymer molar fraction in the liquid crystal polyester of Synthesis Example 2 was 55.0 mol %:22.5 mol %:22.5 mol % when represented as the molar fraction of the structural unit represented by the above-mentioned formula (1) to the structural unit represented by the above-mentioned formula (2) to the structural unit represented by the above-mentioned formula (3). In addition, the copolymer molar fraction of 2,6-naphthalenediyl groups to the total number of aromatic groups contained in these structural units in the liquid crystal polyester of Synthesis Example 2 was 72.5 mol %.

### Synthesis Example 3

After raising the temperature of a powder obtained in the same manner as Synthesis Example 1 from 25° C. to 250° C. over the course of 1 hour, the temperature was raised from the same temperature (250° C.) to 310° C. over the course of 10 hours followed by holding at the same temperature (310° C.) for 5 hours to carry out solid phase polymerization. Following solid phase polymerization, the resulting powder was subsequently cooled to obtain powdered liquid crystal polyester. This was designated as Synthesis Example 3.

The substantial copolymer molar fraction in the liquid crystal polyester of Synthesis Example 3 was 55.0 mol %:22.5 mol %:22.5 mol % when represented as the molar fraction of the structural unit represented by the above-mentioned formula (1) to the structural unit represented by the above-mentioned formula (2) to the structural unit represented by the above-mentioned formula (3). In addition, the copolymer molar fraction of 2,6-naphthalenediyl groups to the total number of aromatic groups contained in these structural units in the liquid crystal polyester of Synthesis Example 3 was 72.5 mol %.

### Synthesis Example 4

911 g (6.6 moles) of p-hydroxybenzoic acid, 409 g (2.2 moles) of 4,4′-dihydroxybiphenyl, 91 g (0.55 moles) of isophthalic acid, 274 g (1.65 moles) of terephthalic acid and 1235 g (12.1 moles) of acetic anhydride were added to the same reactor as Synthesis Example 1 followed by stirring. Next, 0.17 g of 1-methylimidazole were added, and after adequately replacing the atmosphere inside of the reactor with nitrogen gas, the temperature was raised to 150° C. over the course of 15 minutes in the presence of flowing nitrogen gas, followed by refluxing for 1 hour while holding at that temperature. Subsequently, after adding 1.7 g of 1-methylimidazole, the temperature was raised to 320° C. over the course of 2 hours 50 minutes while distilling off distilled by-product acetic acid and unreacted acetic anhydride, and the reaction was considered to have been completed at the point an increase in torque was observed, followed by removal of the contents from the reactor. The liquid crystal polyester obtained in this manner was cooled to room temperature and crushed with a grinder to obtain powdered liquid crystal polyester (prepolymer) having a particle diameter of about 0.1 mm to 1 mm.

After increasing the temperature of the resulting powder from 25° C. to 250° C. over the course of 1 hour, the temperature was raised from the same temperature (250° C.) to 285° C. over the course of 5 hours followed by holding at the same temperature (285° C.) for 3 hours to carry out solid-phase polymerization. Following solid phase polymerization, the resulting powder was subsequently cooled to obtain powdered liquid crystal polyester. This was designated as Synthesis Example 4.

The substantial copolymer molar fraction in the liquid crystal polyester of Synthesis Example 4 was 60 mol %:20 mol %:20 mol % when represented as the molar fraction of the structural unit represented by the above-mentioned formula (1) to the structural unit represented by the above-mentioned formula (2) to the structural unit represented by the above-mentioned formula (3). In addition, the copolymer molar fraction of 2,6-naphthalenediyl groups to the total number of aromatic groups contained in these structural units in the liquid crystal polyester of Synthesis Example 3 was 0 mol %.

<Measurement of Flow Starting Temperature>

The flow starting temperature of the powdered liquid crystal polyester was measured for each of Synthesis Examples 1 to 4. Namely, approximately 2 g of sample were filled into a capillary rheometer equipped with a die having an inner diameter of 1 mm and length of 10 mm using a flow tester (Model CFT-500, Shimadzu Corp.). The temperature at which melt viscosity indicates 4800 Pa·s (48000 poise) when the liquid crystal polyester is extruded from a nozzle at a heating rate of 4° C./min and under a load of 9.8 MPa (100 kgf/cm²) was taken to be the flow starting temperature. These results are collectively shown in Table 1.

In addition, the powdered liquid crystal polyester obtained in each of Synthesis Examples 1 to 4 was granulated into pellets, and the flow starting temperature of the liquid crystal polyester pellets was measured. Namely, 500 g of each liquid crystal polyester of Synthesis Examples 1 to 4 were granulated at a temperature from the flow starting temperature of each liquid crystal polyester to a temperature 10° C. higher than the flow starting temperature with a twin-screw extruder (PCM-30, Ikegai Corp.) to obtain pellets. The flow starting temperature was then measured for the resulting pellets corresponding to Synthesis Examples 1 to 4. These results are collectively shown in Table 1.

<Measurement of Melt Tension>

Since a certain degree of melt tension is required to ensure stable industrial production of the liquid crystal polyester base material, melt tension of liquid crystal polyester pellets was measured for each of the Synthesis Examples 1 to 4. At this time, the melt tension of each of the pellets was measured at a temperature higher than the flow starting temperature of the pellets followed by determination of the maximum value of melt tension. In addition, the temperature at which melt tension of the samples was unable to be measured as a result of being unable to be drawn into the form of a thread was also investigated.

Namely, approximately 10 g of sample were placed in a melt viscosity measuring instrument (Model 1B Capillograph, Toyo Seiki Seisaku-sho, Ltd.) followed by drawing the sample into the form of a thread while heating automatically with a variable speed variable speed winder under conditions of a cylinder barrel diameter of 1 mm and piston pushing speed of 5.0 mm/min, and the tension at which the sample broke was taken to be melt tension (units: N). These results are collectively shown in Table 1.

Furthermore, melt tension of the liquid crystal polyester of Synthesis Example 1 was unable to be measured since the sample was unable to be drawn in the form of a thread at a measurement temperature of 300° C. or lower, while the resin ended up flowing without forming a thread if the measurement temperature was 310° C. or higher. Although melt tension was attempted to be measured within a measurement temperature range of 300° C. to 310° C., since the thread ended up breaking due to excessively low melt tension even through there were cases in which the sample was able to be drawn into the form of a thread, it was not possible to determine melt tension.

TABLE 1

| | Synthesis | Synthesis | Synthesis | Synthesis |
|---|---|---|---|---|
| | Example 1 | Example 2 | Example 3 | Example 4 |
| Flow starting temp. of liquid crystal | 267 | 317 | 333 | 327 |
| polyester (° C.) | | | | |
| Granulation temp. (° C.) | 275 | 325 | 340 | 335 |
| Pellet flow starting temp. (° C.) | 267 | 300 | 308 | 318 |
| Melt tension max. value (10⁻³ N) | 0.98 | 25 | 93 | 14 |
| Measured melt tension value at | Unable to be | 25 [310° C.] | 93 [330° C.] | 14 [350° C.] |
| each measurement temp. (10⁻³ N) | measured | 19 [320° C.] | 60 [340° C.] | 7.8 [360° C.] |
| (measurement temp. shown in | | 12 [330° C.] | 43 [350° C.] | |
| brackets) | | 6.9 [350° C.] | 33 [360° C.] | |
| Temp. at which melt tension unable | — | 305 | 325 | 355 |
| to be measured (° C.) | | | | |

### Example 1

A liquid crystal polyester base material having a thickness of 25 μm was produced using the liquid crystal polyester obtained in Synthesis Example 3. Namely, a powder of this liquid crystal polyester was melted in a single-screw extruder (screw diameter: 50 mm), extruded into a film from a T-die (lip length: 300 mm, lip clearance: 1 mm, die temperature: 350° C.) on the end of the single-screw extruder and cooled to produce a liquid crystal polyester base material having a thickness of 25 μm.

### Comparative Example 1

A liquid crystal polyester base material (Comparative Example 1) having a thickness of 25 μm was produced according to the same procedure as Example 1 using the liquid crystal polyester obtained in Synthesis Example 4.

<Weather Resistance Test>

The strength retention rate of the liquid crystal polyester base materials of Example 1 and Comparative Example 1 was determined as an indicator of weather resistance in order to evaluate the weather resistance of these liquid crystal polyester base materials. Namely, the liquid crystal base materials were irradiated with xenon under the following conditions using an accelerated weather resistance tester (SC700-WN High-Energy Xenon Weather Meter, Suga Test Instruments Co., Ltd.).

Wavelength: Continuous light of 275 nm or more (longer short-

wavelengths cut off with filter)

Intensity: 160 W/m² (lamp output)

Temperature: 65° C. (measured with flat panel thermometer at same location as irradiated surface)

Duration: 60 hours

Strength retention rate was then calculated by dividing the strength of the liquid crystal polyester base material after xenon irradiation by the strength of the liquid crystal polyester base material before xenon irradiation.

As a result, in contrast to the strength retention rate of Comparative Example 1 being 7%, that of Example 1 was 75% (in other words, equal to roughly 11 times that of Comparative Example 1). On the basis of this result, the liquid crystal polyester base material of Example 1 was determined to demonstrate weather resistance that was incomparably superior to that of Comparative Example 1. In addition, when base materials were produced using the liquid crystal polyesters obtained in Synthesis Example 1 and Synthesis Example 2, adequate weather resistance was obtained.

<Water Vapor Permeability Test>

The water vapor permeability of the liquid crystal polyester base materials of Example 1 and Comparative Example 1 was determined as an indicator of water vapor impermeability in order to evaluate the water vapor impermeability of these liquid crystal polyester base materials. Namely, water vapor permeability of the liquid crystal polyester base materials was measured under conditions of a temperature of 40° C. and relative humidity of 90% using a gas transmission rate/moisture permeability measuring instrument (GTR-10X, GTR Tec Corp.) in accordance with JIS K7126 (Method A: differential pressure method).

As a result, in contrast to the water vapor permeability of the liquid crystal polyester base material of Comparative Example 1 being 0.343 g/m²/24 hr, that of the liquid crystal polyester base material of Example 1 was 0.011 g/m²/24 hr (in other words, equal to roughly 1/31 of that of Comparative Example 1). On the basis of this result, the water vapor impermeability of the liquid crystal polyester base material of Example 1 was determined to be extremely high as compared with that of the liquid crystal polyester base material of Comparative Example 1.

### INDUSTRIAL APPLICABILITY

The back sheet for a solar cell of the present invention can be applied to a wide range of applications, including satellite applications (such as artificial satellites, space shuttles or space stations), construction material applications (such as roof tiles, window glass or blinds), watch and calculator applications, roofs of electric vehicles and hybrid vehicles, cases of electronic equipment such as cellular telephones, laptop personal computers or digital cameras, as well as other applications.

### BRIEF DESCRIPTION OF THE REFERENCE SYMBOLS

1: solar cell module, 2: solar cell element, 3: photoelectric conversion cell, 5: sealing material, 6: surface protective glass, 7: back sheet, 9: frame, 10: terminal box

1. A back sheet for a solar cell that contains a liquid crystal polyester base material, wherein
a liquid crystal polyester that composes the liquid crystal polyester base material is formed of structural units represented by the following formulas (1), (2) and (3), and
when a total of divalent aromatic groups Ar¹, Ar² and Ar³ contained in the formulas (1), (2) and (3) is defined to be 100 mol %, a 2,6-naphthalenediyl group is contained at 40 mol % or more in these aromatic groups:
—O—Ar¹—CO— (1)
—CO—Ar²—CO— (2)
—O—Ar³—O— (3)
(where, Ar¹ represents one or more types of groups selected from the group consisting of a 2,6-naphthalenediyl group, 1,4-phenylene group and 4,4′-biphenylene group, Ar² and Ar³ respectively and independently represent one or more types of groups selected from the group consisting of a 2,6-naphthalenediyl group, 1,4-phenylene group, 1,3-phenylene group and 4,4′-biphenylene group, and Ar¹, Ar² and Ar³ may have as a substituent thereof a halogen atom, alkyl group having 1 to 10 carbon atoms, or aryl group having 6 to 20 carbon atoms).

2. The back sheet for a solar cell according to claim 1, wherein a flow starting temperature of the liquid crystal polyester is 280° C. or higher.

3. The back sheet for a solar cell according to claim 1, wherein a maximum value of melt tension of the liquid crystal polyester as measured at a higher temperature than the flow starting temperature is 0.0098 N or more.

4. The back sheet for a solar cell according to claim 1, wherein a water vapor barrier layer is laminated onto the liquid crystal polyester base material.

5. A solar cell module, wherein the back sheet for a solar cell according to claim 1 is provided on the back of a solar cell element.
